(19) United States
(12) Patent Application Publication
(10) Pub. No.: US 2026/0148928 A1
(43) Pub. Date: May 28, 2026

(54) MOBILE RADIATION DETECTOR SYSTEM FOR ION IMPLANTERS

(71) Applicant: Axcelis Technologies, Inc., Beverly, MA (US)

(72) Inventors: Peter DeRosa, Rockport, MA (US); Clifton Brick, North Haverhill, NH (US); Wilhelm Platow, Newburyport, MA (US); Kevin Wenzel, Belmont, MA (US)

(21) Appl. No.: 19/177,720

(22) Filed: Apr. 14, 2025

Related U.S. Application Data
(60) Provisional application No. 63/633,971, filed on Apr. 15, 2024.

(51) Int. Cl. H01J 37/244; H01J 37/30; H01J 37/304; H01J 37/317

(52) U.S. Cl. CPC H01J 37/244; H01J 37/3007; H01J 37/304; H01J 37/3171; H01J 2237/024; H01J 2237/2443; H01J 2237/24507; H01J 2237/31701

(57) ABSTRACT

A mobile detection system that follows the high energy beamline during a tuning phase/startup phase of an ion implantation system or otherwise having a passive mobile monitoring system around the ion implantation system can identify radiation conditions that stationary detection systems outside or even inside the system may have missed or poorly reported data on. A mobile detection system that can move a radiation detector to pinpoint location near the ion implantation system or wafer cassette and take detailed data readings very near the source will provide enhanced abilities to determine radiation conditions and appropriately determine shutdown and cooldown times, thereby improving efficient use of the system.

### CROSS-REFERENCE TO RELATED APPLICATIONS

This application claims the benefit of U.S. Provisional Application Ser. No. 63/633,971 filed Apr. 15, 2024, entitled, “MOBILE RADIATION DETECTOR SYSTEM FOR ION IMPLANTERS”, the contents of all of which are herein incorporated by reference in their entirety.

### FIELD

The present disclosure relates generally to ion implantation systems, and more particularly to monitoring for nuclear reactions in ion implantation systems.

### BACKGROUND

Ion implantation systems are utilized to dope a workpiece, such as a semiconductor wafer, with ions from an ion beam, to either produce n- or p-type doped material, or to form passivation layers during fabrication of an integrated circuit. Such beam treatment is often used to selectively implant the wafers with a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. When implanting ions into silicon wafers, ions generated from source materials such as antimony, arsenic, or phosphorus, for example, result in an “n-type” extrinsic material wafer, whereas a “p-type” extrinsic material wafer often results from ions generated with source materials such as boron, gallium, or indium. When implanting ions into silicon carbide (SiC) wafers, for example, nitrogen (n-dopant) and aluminum (p-dopant) are conventionally used as ion species. In addition, light ions, such as hydrogen or helium, are being used as implant species to reduce minority carrier lifetime, improve switching speed and reduce switching losses in Insulated-Gate Bipolar Transistors (IGBT).

In an ion implanter, an ion source generates ions of desired atomic or molecular dopant species. These ions are extracted from the ion source by the ion extraction device, which are typically a set of electrodes that energize and direct the flow of ions from the ion source, forming an ion beam. Desired ions are separated from the ion beam in the mass analysis device, which is typically a magnetic dipole performing mass dispersion or separation of the extracted ion beam. The beam transport device, which is typically a vacuum system containing a series of focusing and acceleration/deceleration devices, transports the analyzed ion beam to the wafer processing device while maintaining desired properties of the ion beam. Finally, semiconductor wafers or other targets for implantation are transferred into and out of a wafer processing device via a wafer handling system, which may include one or more robotic arms, for placing a wafer to be treated in front of the analyzed ion beam and removing treated wafers from the ion implanter.

In many such systems, the wafers, before and after treatment are held in a workpiece cassette such as a front opening unified pod (FOUP), and the wafers are transported out of the wafer cassette for treatment then back into the wafer cassette in a holding area after treatment by the wafer handling system. The wafer cassette is then moved away from the ion implantation system and another wafer cassette is moved into place in the operable range of the wafer handling system.

For many ion implantation systems, the physical size of the ion beam is smaller than a target workpiece, whereby the ion beam is scanned in one or more directions to adequately cover a surface of the target workpiece. Generally, an electrostatic or magnetic based beam scanner scans the ion beam in a fast direction and a mechanical device moves the target workpiece in a slow scan direction to provide sufficient coverage of the ion beam across the surface of the workpiece.

Ion implantation systems can produce unwanted beam strikes on interior parts of the system. This can be due to initial calibrations, miscalibration of the equipment, or improper installation of components or materials. This can cause particle emissions imparting ionizing radiation and breakdowns of the linings in certain chambers or the chamber walls themselves. Ion implantation systems are highly tuned instruments that require high precision, and, if not carefully tuned, at some point an unwanted beamstrike may occur. For example, the operation of the ion implantation system with high-energy beams has the possibility of eroding or sputtering away protective liners within the beam line. Liners are frequently used that run along a portion of the beamline in a chamber of the ion implantation system to prevent semiconductor wafers from being exposed to unwanted contaminants sputtered from the beamline walls (especially heavy metals). In the case of high-energy beams, the liners can also be used to prevent nuclear reactions between light high-energy ion species (e.g., hydrogen) and other elements such as graphite or aluminum. Erosion of the liners that exposes undesired elements can cause unwanted nuclear reactions from beam line material collisions.

In addition, unwanted reactions from the beam can be caused if an incorrect material, e.g., a heavy metal, that is mistakenly inserted into the system, for example, inserted into the end chamber, or utilized as a faraday cup, or as a liner. For example, if a titanium material is hit with hydrogen ion at energy above 800 keV, it will produce a fusion reaction with gamma-ray photon emissions.

### SUMMARY

In accordance with advances in high-energy implant processes with light species, it has become desirable to monitor radiation conditions at various locations within an ion implant system. There are potential nuclear fusion reactions caused by impacts on beamline material layers by light implant species, such as H+. Rather than building in a default processing system delay to allow for radiation from implanted wafers and/or beamline components to be resolved, the mobile tracking system of the disclosure is able to provide more precise information on when any system radiation has decayed to acceptable limits. Additionally, there will always be unforeseen issues with beam species build up inside the beamline components exposed to beam strike, and running the wrong accelerated beam into these deposits can produce radiation that could be missed by a stationary detection system. These unforeseen reactions can also lead to decaying radiation going undetected. Thus, it is important for maintenance efficiency to know when and where the beamline equipment is no longer radioactive. In addition, the tracking system of the present application is configured for mobile use around the entire ion implantation system or a subsection thereof to better track individual instances of potential radioactivity.

Accordingly, the following presents a simplified summary of the disclosure to provide a basic understanding of some aspects of the disclosure. This summary is not an extensive overview of the disclosure. It is intended to neither identify key or critical elements of the invention nor delineate the scope of the invention. Its purpose is to present some concepts of the disclosure in a simplified form as a prelude to the more detailed description that is presented later.

In some aspects, the techniques described herein relate to a system including: a mobile detector system associated with an ion implantation system; the ion implantation system including: an ion source that generates ions and produces an ion beam along a beamline, a mass analyzer positioned downstream of the ion source that generates a magnetic field; and an ion accelerator downstream of the mass analyzer; the mobile detector system including: a railway extending around at least a portion of the ion implantation system or a holding station for a workpiece cassette; and a mobile detector moveably coupled to the railway and including a radiation detector.

In some aspects, the techniques described herein relate to a method of conducting ion implantation operations including the operations of: conducting ion implantation on a workpiece or calibrating an ion implantation system; detecting radiation at a mobile detector, the mobile detector moveably coupled to a railway; determining if detected radiation is anomalous; if anomalous radiation is detected, then moving the mobile detector to a source of the anomalous radiation, wherein moving the mobile detector to a source of the anomalous radiation includes moving the radiation detector closer to the ion implantation system or workpiece; determining if the anomalous radiation warrants shutdown of the ion implantation system.

In some aspects, the techniques described herein relate to a system including: a mobile detector system associated with a holding station for a workpiece cassette, including: the mobile detector system including: a railway extending around at least a portion of the holding station for a workpiece cassette configured to house workpieces; a mobile detector moveably coupled to the railway; the mobile detector including an arm with a radiation detector coupled to an end of the arm; the mobile detector configured to move to a side of a workpiece cassette, and change position to be within 10 cm of a most recently implanted workpiece after the most recently implanted workpiece enters the workpiece cassette; the mobile detector system configured to monitor the workpieces for a radiation anomaly and provide an alert regarding a detected radiation anomaly to an operator on a display.

The above summary is merely intended to give a brief overview of some features of some embodiments of the present disclosure, and other embodiments may comprise additional and/or different features than the ones mentioned above. In particular, this summary is not to be construed to be limiting the scope of the present application. Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings. Furthermore, the features of the various embodiments and examples described herein may be combined with each other unless specifically noted otherwise.

### BRIEF DESCRIPTION OF THE DRAWINGS

FIG. 1 is a simplified top view illustrating an exemplary system comprising an ion implantation system and mobile detector system in accordance with an aspect of the present disclosure.

FIG. 2 is a cross-sectional view of an example of a portion of an ion implantation system in accordance with an aspect of the present disclosure.

FIG. 3 is a simplified top view illustrating another exemplary system comprising an ion implantation system and mobile detector system in accordance with an aspect of the present disclosure.

FIG. 4 is a simplified top view illustrating another exemplary system comprising an ion implantation system and mobile detector system in accordance with an aspect of the present disclosure.

FIG. 5 is a side view an exemplary mobile detector in more detail.

FIG. 6 is a perspective view of another embodiment of a mobile detector system that is a workpiece radiation dosimetry monitoring system that measures the activated or decaying radioactive isotopes within implanted wafers after they enter a workpiece cassette.

FIG. 7 is a flowchart of an example method for mobile detection of radiation in an ion implantation system, processing the signal received therefrom, and operating the ion implantation system.

FIG. 8 is a continuation of the method of claim 7, wherein post-shutdown activities are disclosed.

FIG. 9 is a graph of data capturing radiation decay data from the ¹³N production from the ¹²C(p, γ)¹³N fusion reaction on a Purion XEmax implanter.

FIG. 10 is a graph showing radiation detected from a 3E¹⁴ H+ implant provided from a Purion VXE implanter.

### DETAILED DESCRIPTION

In an example, a semiconductor manufacturing system includes a radiation detector that is robotically moveable about the system and capable of near range examination of radiation anomalies. In addition, the system includes a controller that communicates with the mobile detector and can shut down the system if a type or threshold level of nuclear radiation is detected.

Recent applications in ion implantation beam species and beam energies have now exceeded the fusion barrier in many materials found in wafers, potentially creating radioactive wafers post-implant. This can potentially affect device throughput (e.g., requiring extended wait times) for the maintenance of irradiated beam line materials and using any type of semiconductor fabrication wafers. Having a physical radiation detector, near (or as close to the radioactive source in the beam line or wafer as possible) can prevent user access to the wafers prior to a minimum amount of time needed for radioactive decay.

Radioactive isotopes can be formed during nuclear excitation reactions within the beamline, leaving the beamline components emitting 511 keV photons as the parts themselves beta-decay back to stability or non-radioactive isotopes. Knowing where these decaying hot spots are can be difficult when considering beam focusing. If a beam “blows up,” losing its focus and scattering onto the walls, it is difficult to determine the strike points.

Additional examples of this problem are now emerging with the use of light ion implants within wafers that can result in nuclear reactions based on different wafer types such as Si, GaAs, SiC, and borosilicate glass. Materials in beamlines that are of particular concern are graphite and aluminum. Graphite is a widely used beamline component material for liners and other faradays components due to its ideal physical properties. However, at accelerated energies of H+ above 457 keV, there are fusion reaction resonances, causing the production of high energy gamma-ray photons from the ¹²C(p, γ)¹³N fusion reaction. ¹³N has a half-life of 9.959 [mins]. Aluminum also presents nuclear fusion concerns.

Wafers that may be used in the light ion implantation may comprise, for example, GaAs, SiC, and borosilicate glass type wafers. GaAs wafers contain about 50% Ga and about 50% 75As. ⁶⁹Ga is present in a total concentration of about 30%, and ⁷¹Ga is in a total concentration of about 20% in the wafer.

SiC wafers contain about 50% C and about 50% Si. ¹²C is present in about 49.35% concentration and ¹³C is present in about 0.51% total concentration in the wafer. ²⁸Si is present in about a 46.1% total concentration, ²⁹Si is present in about 2.3% total concentration, and ³⁰Si is present in about 1.55% concentration of the total wafer.

Borosilicate glass wafers contain about 75% to 80% silica SiO₂, about 8 to 12% boric acid (B₂O₃) and about 5% or less aluminum oxide (Al₂O₃). (Other alkaline oxides or potassium oxides may also be present.) Regarding silica isotopes, about 1.15% of the total wafer is ²⁹Si. About 1.4% of the total wafer is ¹⁰B and about 5.6% of the total wafer is ¹¹B. Aluminum concentration is about 3%.

Table 1 shows nuclear reactions with respect to decay type, relative concentration pertaining to certain wafer types, energy threshold, and the half-life of the daughter nucleus. Source: Brown, D. (Ed.). (n.d.). National Nuclear Data Center.

TABLE 1

| | Abundance | H+ Energy | Daughter |
|---|---|---|---|
| Reaction | (Wafer Type) | threshold | T½ |
| ²⁹Si (p, γ)³⁰P | 4.68% | 326 | 2.498 |
| | (Si) | [keV] | [mins] |
| ¹²C (p, γ)¹³N | 46.1% | 415 | 9.959 |
| | (SiC) | [keV] | [mins] |
| ⁷¹Ga(p, n)⁷¹Ge | 20% | 1000 | 11.43 |
| | (GaAs) | [keV] | [days] |
| ⁷⁵As(p, n)⁷⁵Se | 50% | 1700 | 119.78 |
| | (GaAs) | [keV] | [days] |
| ¹¹B(α, p)¹⁴C | 5.6% | 800 | 5700 |
| | (Glass) | [keV] | [years] |
| ¹²C(p, γ)¹³N | 46.1% | 415 | 9.959 |
| | (SiC) | [keV] | [mins] |
| ¹⁰B(α, n)¹³N | 19.90% | 1000 | 9.959 |
| | (Glass) | [keV] | [mins] |

Nuclear reactions in Table 1 describe the most prominent problems faced inside a wafer. With newer light ion implantations and liner materials (e.g., graphite and aluminum) these reactions can take place instead in the beamline. These reactions could also result from a beam species build up on a faraday cup with common beam species, such as, but not limited to, boron, arsenic, or phosphorous. Having different deposits of other beam species inside the machine during operation of light ion accelerated beams can lead to for unforeseen radiation hot spots that a stationary detector can miss.

As ion implantation systems are operated at higher energies with lighter species, there is a heightened chance of operators unintentionally creating nuclear reactions in the liner or other materials in the beamline. This can be caused by mistuning of the system components, operator error in using an improper material in a particular location, or some unintended buildup on a faraday cup as discussed above. For example, if a magnet is mistuned, it can cause a high energy ion beam to strike a material that it has sufficient energy to produce a fusion reaction with.

Having a mobile detection system that follows the high energy beamline during a tuning phase/startup phase of the implanter, or otherwise having a passive mobile monitoring system around the ion implantation system can identify radiation generation that stationary detection systems outside or even inside the system may have missed or poorly reported data on. A mobile detection system that can move a radiation detector to pinpoint location near the ion implantation system or wafer cassette and take detailed data readings very near the source will provide enhanced abilities to determine radiation conditions and appropriately determine shutdown and cooldown times, thereby improving efficient use of the system.

For example, an ion implantation system with a stationary detector may provide an alert that there was a beamstrike that generated radiation. This could require a prolonged shutdown of the device, a wait time for the radiation to subside to acceptable levels and further time spent searching for the specific beamstrike area. With the mobile detection system disclosed herein, once radiation is detected the mobile detection can be sent out within its range of motion to zero-in on the radiation source, move the detector in close to this area and take detailed readings. The problem can then be addressed more quickly since the wait time margins are better defined with better data, and the specific location of the beamstrike/radiation source can be ascertained remotely and automatically without even waiting for the radiation to subside.

Wait time for performing maintenance on the system at close range after a beamstrike in the area is also improved by having a mobile detection system that can closely observe the area and get direct readings of what radiation the operator's hands, head, or other body parts will encounter in that area. This is in contrast to having to rely on longer distance detection coupled with complex computations involving quantum thermodynamics to approximate the radiation exposure.

The mobile detection system also addresses another challenge in the ion implantation system. A problem exists for stationary detector systems for wafer applications, in that the wafer location can vary in the workpiece cassette, e.g., the FOUP. Because of the geometric and material effects, e.g., distance, angle, and intervening materials blocking the detector, the radiation detected can greatly change in intensity and accuracy for radiation dosimetry analysis. By utilizing a mobile radiation detector the geometric and material effects can be normalized in real time by following the wafer location on the side of the wafer carrier, such that there is always the same distance from the source being analyzed. This will allow a hardware control for the wafer radioactive decay dosimetry monitoring without having to perform complex and customized calculations for each use scenario.

In an embodiment, the mobile detection system for an ion implantation system disclosed herein includes a mobile radiation sensor (e.g., a photon-energy resolving crystal detector), mounted with electronics for signal processing (optionally) and detection. The technology disclosed herein combines cutting-edge energy spectroscopy techniques particularly suited for high-energy low atomic weight ion implantation systems with a mobile detector system.

Semiconductor manufacturing systems, such as, for example, ion implantation systems, include chambers that are under vacuum and are being bombarded by particle streams or other operations during use.

The present disclosure is directed generally toward a mobile detector system and method associated with implantation of ions into a workpiece or other semiconductor manufacturing processes. The technology is described with reference to the drawings, wherein like reference numerals may be used to refer to like elements throughout. It is to be understood that the description of these aspects is merely illustrative and that they should not be interpreted in a limiting sense. In the following description, for purposes of explanation, numerous specific details are set forth in order to provide a thorough understanding of the technology described herein. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as exemplary only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components for all embodiments encompassed by this disclosure.

It is also to be understood that in the following description, any direct connection or coupling between functional blocks, devices, components, or other physical or functional units shown in the drawings or described herein could also be implemented by an indirect connection or coupling. Furthermore, it is to be appreciated that functional blocks or units shown in the drawings may be implemented as separate features or components in one embodiment, and may also or alternatively be fully or partially implemented in a common feature or component in another embodiment.

In ion implantation, dopant atoms/molecules are ionized and isolated, sometimes accelerated or decelerated, formed into a beam, and swept across a workpiece or wafer. The dopant ions physically bombard the workpiece, enter the surface, and typically come to rest below the workpiece surface in the crystalline lattice structure thereof. In light ion, high-energy ion implantation, the ions are selected from elements with an atomic number of 11 or less, such as 7 to 2, or 3 to 1. For example, ions such as H, He, Li, Be, and B, may be generated in the ion source. In an example of higher mass beam species, C, N, O, F, Ne, P, and As can also be generated in the ion source. These ions are accelerated to high energy states, such as at or above 300 keV, for example, 400 keV to 15 MeV, such as 500 keV to 10 MeV, or 1 MeV to 5 MeV.

Accelerator systems that conduct higher energy beams, or rather the acceleration of ion beams above 400 keV, may utilize a LINAC structure using resonators, cavities, and/or RF gap style systems; they may also utilize a tandem acceleration scheme or radio frequency quadrupole (RFQ) acceleration. The use and implementation of these devices use energy resolving slits or ERS, usually coupled with magnets, to isolate the final energy exiting the acceleration structure of the machine. The combination of a LINAC block with an ERS and magnet for energy resolving is often used in high energy systems.

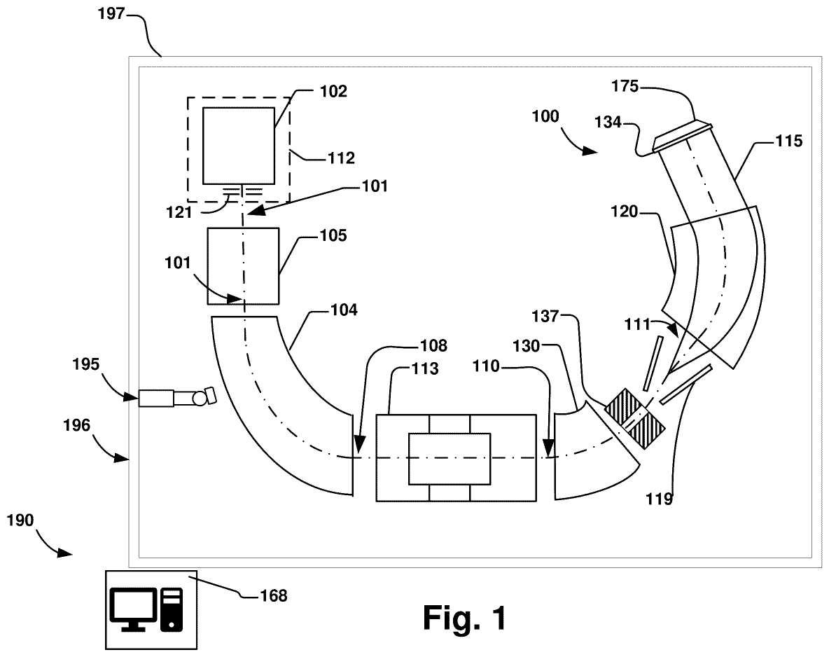

Referring now to the figures, the components of the ion implantation system 100 are now described in more detail, followed by the components of the exemplary mobile detector system 190. In accordance with one exemplary aspect of the present disclosure, FIG. 1 illustrates an exemplary hybrid parallel scan single wafer ion implantation system 100. The ion implantation system 100 is also referred to as a post acceleration implanter, since a main accelerator 113 is placed after a mass analyzer 104 and before an energy filter 130. Ion implantation systems 100 of this type often (as shown) have the energy filter 130 after (i.e., further from the ion source 102 along the beamline) the main accelerator 113 to remove unwanted energy spectrum in the output of the main accelerator 113.

In this exemplary ion implantation system 100, an ion beam 101 generated from the ion source 102 is accelerated by an optional pre-mass analyzer accelerator 105 that is positioned before the mass analyzer 104 to generate an accelerated and analyzed ion beam 108. Downstream, the accelerated and analyzed ion beam 108 may be further accelerated in the main accelerator 113 by a plurality of accelerator stages therein. For example, the accelerator stages may comprise resonators (as with an RF accelerator) respectively to generate RF acceleration fields therein and output an accelerated ion beam 110 that has been further accelerated. After passing through the energy filter 130, the filtered ion beam 111 goes through a beam scanner 119 and then through an angle corrector lens 120 to convert the filtered ion beam 111 into a parallel shifted ion beam 115.

A workpiece 134 is moved orthogonal (shown as moving in and out of the paper) to the parallel shifted ion beam 115 in the hybrid scan scheme to irradiate the entire surface of the workpiece 134 uniformly. Other types of scanning can also be used with the monitoring and associated technology described herein. As stated above, various aspects of the present disclosure may be implemented in association with any type of ion implantation system, including, but not limited to the exemplary mobile detector system 190 for an ion implantation system 100 of FIG. 1.

The source chamber assembly 112 comprises the ion source 102 and an ion extraction electrode assembly 121 to extract and accelerate ions to an intermediate energy. To generate the ions, a gas of a dopant material to be ionized is located within an ion generation chamber (not shown) of the ion source 102. The dopant gas can, for example, be fed into the source chamber assembly 112 from a gas source (not shown). It will be appreciated that one or more suitable mechanisms (not shown) can be used to excite free electrons, such as, for example, RF or microwave excitation sources, electron beam injection sources, electromagnetic sources and/or a cathode which creates an arc discharge within the chamber. The excited electrons collide with the dopant gas molecules and ions are generated thereby. Typically, positive ions are generated although the disclosure herein is applicable to systems wherein negative ions are generated as well.

The ions are controllably extracted through a slit in the ion extraction electrode assembly 121. The ion extraction electrode assembly 121 comprises a plurality of extraction and/or suppression electrodes. The ion extraction electrode assembly 121 can include, for example, a separate extraction power supply (not shown) to bias the extraction and/or suppression electrodes to accelerate the ions from the source chamber assembly 112. It can be appreciated that since the ion beam 101 comprises like-charged particles, the beam may have a tendency to expand radially outwardly as the like charged particles repel one another. It can also be appreciated that beam expansion can be exacerbated in low energy, high current (high perveance) beams where many like charged particles (e.g., high current) are moving in the same direction relatively slowly (e.g., low energy) such that there is an abundance of repulsive forces among the particles, but little particle momentum to keep the particles moving in the direction of the beam path. Accordingly, the ion extraction electrode assembly 121 is generally configured so that the beam is extracted at a high-energy so that the beam does not expand unduly (e.g., so that the particles have sufficient momentum to overcome repulsive forces that can lead to beam expansion), which would lead to beam current loss.

The pre-analyzer accelerator 105 further accelerates the ions and is an optional component, which may be unneeded for some operations.

The mass analyzer 104 generates a magnetic field according to a selected charge-to-mass ratio and performs an angle adjustment to the ion beam 101. The mass analyzer 104, in this example, is configured to bend the ion beam 101 at about a ninety-degree angle and comprises one or more magnets (not shown) that serve to establish a (dipole) magnetic field therein. As the ion beam 101 enters the mass analyzer 104, it is correspondingly bent by the magnetic field such that ions of an inappropriate charge-to-mass ratio are rejected. More particularly, ions having too great or too small a charge-to-mass ratio are deflected into side walls of the mass analyzer 104. In this manner, the mass analyzer 104 mainly allows those ions in the beam 101 which have the desired charge-to-mass ratio to pass there-through and in an example exit through a mass resolving aperture, which can further adjust the ion beam 101. It will be appreciated that collisions of the ion beam 101 with other particles in the system 100 can degrade beam integrity. Accordingly, one or more pumps (not shown) may be included to evacuate parts of the system, for example, the mass analyzer 104.

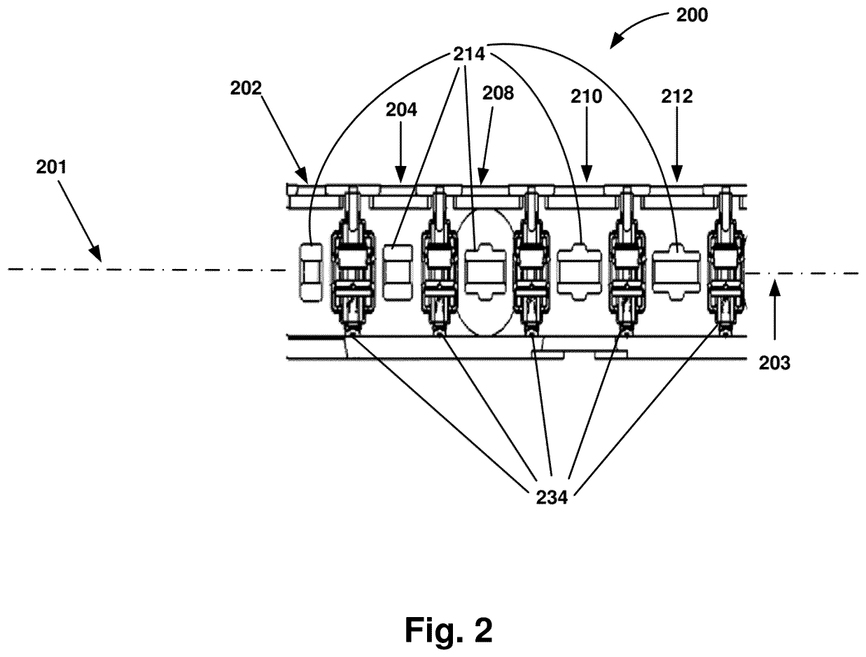

The main accelerator 113 accelerates the ions to a higher energy. The accelerator 113, for example, can be an RF linear particle accelerator (LINAC), in which ions are accelerated repeatedly by an RF field, or a DC accelerator (e.g., a tandem electrostatic accelerator), which accelerates ions with a stationary DC high voltage. The main accelerator 113 is described further with respect to FIG. 2 below.

After the accelerated ion beam 110 exits the main accelerator 113, it is further conditioned by an energy resolving slit (ERS) 137. The ERS 137 is a structure and method that collimates the energy distribution of transported accelerated particles exiting a LINAC block assembly. The energy resolution of a given beam can be tuned by how wide the slit is in the presence of the beam and by what amplitudes and phases are selected. Often coupled with a dipole bending magnet, where the trajectory of the higher energy ions will have less curvature than lower energy ions within a given accelerated beam. Using this, one can introduce an acceptance to make the energy distribution a fixed value. For example, the width of a “standard” ERS could be an energy distribution/resolution of +/−5% of the desired accelerated beam energy, to which the operator could change that resolution to 10% or 0.05% depending on the relative slit width of the allowed beam as it comes out of dipole magnet from the LINAC.

The beam scanner 119, either electrostatically or electromagnetically scans the accelerated ion beam 110, typically left to right, into the angle corrector lens 120, which converts the filtered ion beam 111 into the parallel shifted ion beam 115.

The angle corrector lens 120 causes the filtered ion beam 111 to alter its path such that the ion beam travels parallel to a beam axis regardless of the scan angle. As a result, the implantation angle is relatively uniform across the workpiece 134 and normalized to eliminate vertical deviations of the beam, making it almost horizontal moving towards its final destination. The angle corrector lens 120 can be an electromagnetic magnet as shown, but can also be electrostatic, for example. The final parallel shifted ion beam 115 that results from the angle corrector lens 120 is directed onto the workpiece 134.

The workpiece 134, if not present, occupies the same space as a workpiece target (as further explained above) and is held by a workpiece support 175, which can be housed in a process chamber or end station (not shown). It is appreciated that different types of end stations and workpiece supports 175 may be employed in the ion implantation system 100. For example, a “batch” type end station can simultaneously support multiple workpieces 134 on a rotating workpiece support structure, wherein the workpieces are rotated through a parallel shifted ion beam 115 until all the workpieces are completely implanted. Such a “batch” type implanter does not require a scanner and corrector lens. A “serial” type end station, on the other hand, supports a single workpiece 134 along the parallel shifted ion beam 115 for implantation, wherein multiple workpieces are implanted one at a time in serial fashion, with each workpiece being completely implanted before implantation of the next workpiece begins. In hybrid systems, the workpiece 134 may be mechanically translated in a first direction (the y-direction or so-called “slow scan” direction) while the parallel shifted ion beam 115 is scanned in a second direction (the x-direction or so-called “fast scan” direction) to impart the parallel shifted ion beam 115 over the entire workpiece 134.

FIG. 2 illustrates one example of a portion of an ion implantation system in accordance with one aspect of the disclosure. An accelerator 200, which can be the main accelerator 113 of FIG. 1, can comprise an RF accelerator, which is illustrated in FIG. 2 as one example of an embodiment, and can comprise a number of accelerator stages (e.g., 202, 204, 208, 210, and 212). The accelerator stages 202, 204, 208, 210, and 212 can respectively comprise at least one accelerator electrode 214 which is driven by an RF resonator, for example, for generating an RF accelerating field on both sides (not shown). An ion beam 201 of charged particles with a charge state (e.g., a net electrical charge or a valence) can pass through apertures of the accelerator electrodes 214 in succession.

Beam focusing can be provided by lenses 234 (e.g., electrostatic or magnetic quadrupole) incorporated within the accelerator 200. In one embodiment, the accelerator 200 can accelerate charged ions to a kinetic energy level at or exceeding 10 keV or at or exceeding 300 keV when the accelerated beam exits the accelerator 200. In an example, a lens 234 is included in each accelerator stage (202, 204, 208, 210, and 212).

There is not one particular accelerator or type of LINAC that the present disclosure is confined to. The number of stages is not confined to the illustration of FIG. 2, and can be, for example, 1 to 50 accelerator stages, such as 2 to 10, or 3 to 6. In addition, the accelerator could be a tandem accelerator or RFQ.

FIG. 1 also discloses the mobile detection system 190 that comprises a mobile detector 195 that is moveably coupled to a railway 196 that extends around at least a portion of the ion implantation system 100. In one embodiment, the railway 196 extends around the entire ion implantation system 100, encircling it and providing a closed circuit for the mobile detector 195 to rotate around the ion implantation system 100. The mobile detector 195 can travel in a forward or reverse direction to approach the desired end location.

The term “railway” is not meant to be limited to a rail, such as a rail for a carrier coupled to the rail, but is meant to include such things as a tube, wherein a carrier including a radiation detector is moveable within the tube, or a cable that moves along a track or pathway. Rather the term “railway” should be construed broadly to be an elongated structure configured to move a coupled carrier along a pathway. For example: a tube or cable could be a “railway” that could be used to direct the location of a mobile detector to the areas of concern as discussed in the specific embodiments below.

In another embodiment, the railway 196 extends only along a partial extent of the ion implantation system 100, such as, for example, only running along three sides of the ion implantation system 100. In this embodiment, the side 197 nearest both the ion source 102 and the workpiece support 175 is open. The mobile detector 195 in this case, travels along the railway 196 in two directions, reversing course when it comes to an end of the railway 196.

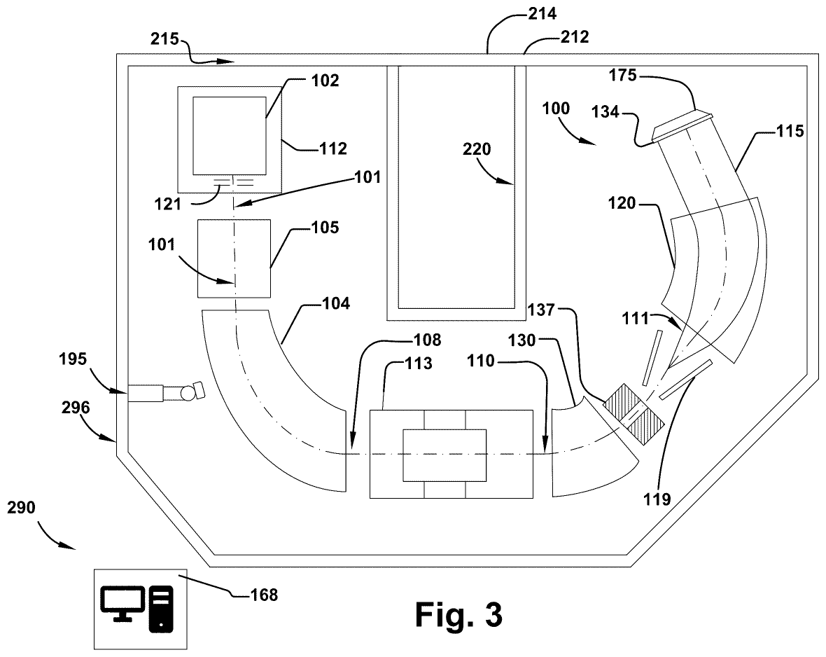

FIG. 3 is a diagram of another embodiment of the mobile detector system 290 wherein the railway 296 more closely follows the contours of the exterior of the ion implantation system 100. In an embodiment, the railway 296 is configured to be at relatively consistent distance from the exterior of the ion implantation system 100. For example, the railway 296 is configured to vary no more than 1 to 0.01 feet, such as 0.5 to 0.05 feet, or 0.25 to 0.1 feet in distance from the exterior of the ion implantation system 100. In an embodiment, the railway 296 may be 1 to 10 feet from the exterior of the ion implantation system, such as 1.5 to 7 feet, or 2 to 4 feet on average from the ion implantation system.

Also disclosed in FIG. 3 is an inner loop 220 of the railway 296. The inner loop 220 is coupled to the outer section 217 of the railway 296. In the inner loop 220, the mobile detector 195 can move to a location on an opposite side of the exterior of the ion implantation system 100 to get a closer and better reading on any detected radiation anomalies on that side of the system 100.

In an embodiment, the inner loop 220 is coupled to the outer section 217 of the railway 296 with a first switch 213 and second switch 215 that are configured to be moved to allow the mobile detector 195 to enter the inner loop 220, exit the inner loop 220, or to bypass the inner loop 220 or bypass the outer section 217. This allows a faster transition by the mobile detector 195, e.g., from the upper right side of the outer section 217 to the upper left side of the outer section 217 or from the upper right side of the inner loop 220 to the upper left side of the inner loop 220.

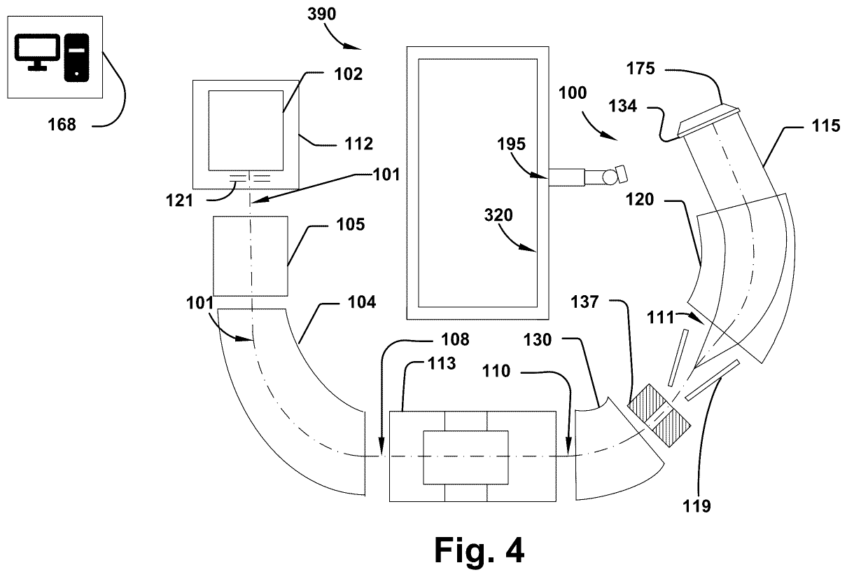

FIG. 4 is another embodiment of an exemplary mobile detector system 390. In this embodiment, the railway 320 consists of only an inner loop as described above.

In another embodiment (not shown), the railway is located above the ion implantation system 100, and it follows the ion beam 101. The railway may be suspended from the ceiling of the facility or may be supported above the ion implantation device with supports coupled to the exterior of the ion implantation system 100 or to the floor. In this embodiment, the mobile detector 195 extends down from the railway and can run in one or both directions in an open circuit or in two directions in an open circuit formation. In the open circuit formation, the railway may start at the ion source 102 and end at the workpiece support 175.

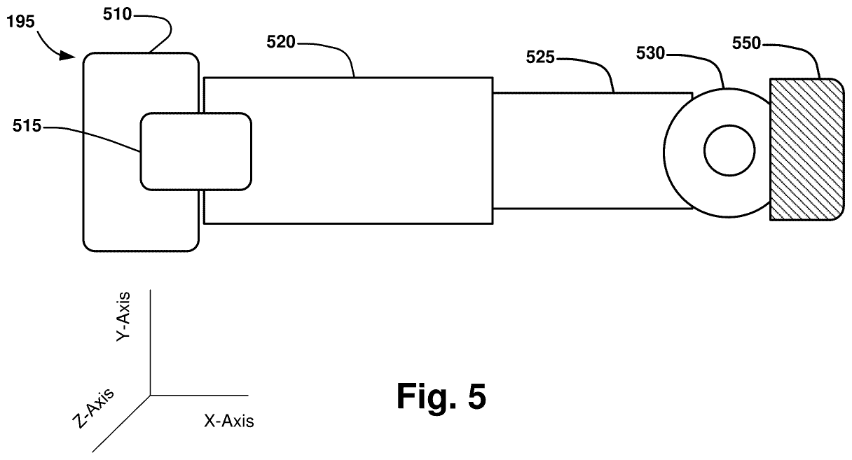

Each of the above embodiments utilizes a mobile detector 195. FIG. 5 discloses an exemplary mobile detector 195 in more detail. The mobile detector 195 is a robotic arm moveably coupled to the railway (e.g., any railway 196, 296, 396 disclosed above). In this embodiment, the mobile detector 195 includes base 510 that provides the coupling mechanism to the railway. The base 510 can include features that allow it to be inserted and retained on a track of the railway. In an embodiment, the track of the railway moves, e.g., like a driven belt with a flexible material belt, or interlocking plastic or metal chain-like segments. In such an embodiment, the base 510 is configured to be affixed to the driven belt or the flexibly interlocked segments.

In another embodiment, the base 510 has an internal motor that drives the mobile detector 195 around the railway. The motor may be coupled to wheels on one or both sides of a stationary tubular or flattened rail surface in the railway. For example, if the railway is on the side of the ion implantation system 100, wheels on both sides (sides facing and opposite facing the mobile detector 195) of the stationary tubular or flattened rail surface may be needed for stability. If the railway is overhead, only one set of wheels on the side opposite the mobile detector 195 may be used. In an embodiment, the base 510 is configured to travel in a z-direction or a y-direction. In an embodiment, the mobile detector has at least two degrees of freedom of motion apart from the motion imparted by moving along the railway 196.

For the railway 320 of FIG. 4, the railway may be suspended from the ceiling, supported from the floor, e.g., with stabilized pylons, at a height of, e.g., 2 feet to 8 feet, and more specifically, such as 3 feet to 5 feet. A floor mounted track could also be used with the mobile detector 195 including a vertical post before the base 510. For the railways 196, 296 of FIG. 1 and FIG. 2, all these mounting options are available, but the railway could also be mounted on the wall surrounding the ion implantation system 100.

The base 510 is coupled to a first arm 520 of the mobile detector 195. In an embodiment, the base 510 is coupled to the first arm 520 through a motorized hinge unit 515. The hinge unit 515 allows the first arm 520 to have a range of motion in a z-direction. Alternatively, the hinge unit 515 can be configured to allow the first arm 520 to have a range of motion in a y-direction and/or z-direction. Movement along the y- and/or z-axis allows the mobile detector to pinpoint locations and adjust angles of approach to various areas of the ion implantation system 100.

The first arm 520 is slidably coupled to a second arm 525. The second arm 525 has a smaller diameter than the first arm 520 and can be retracted into or out of an interior of the first arm 520. Electric linear actuators may be used to drive the second arm 525 in and out in the x-axis direction. Movement along the x-axis direction allows the mobile detector 195 to adjust for any inconsistencies in how close the railway is to the ion implantation system 100, and also allows the mobile detector 195 to get as close as possible to the source of radiation to take near vicinity readings.

In an embodiment, a third arm could be slidably coupled to the second arm 525, and additional arms could be added thereafter in a similar manner to extend the mobile detector 195 as needed.

In the embodiment of FIG. 5, the second arm is coupled to the radiation detector 550 via a second hinge 530. The second hinge 530 rotates to move the radiation detector 550 in a z-direction (into and out of the page) and/or y-axis direction (up and down). This movement allows the radiation detector 550 to obtain an optimal angle pointing towards the radiation source.

Because the high-energy radiation of concern is not contained by the walls or chamber linings of the ion implantation system, the mobile detector 195 can be located outside the walls of the system and still detect the radiation of interest. However, as discussed above, the mobile detector 195 should be placed as near the outer walls of a component or chamber of the system 100 as possible where the radiation is detected, such as, for example, immediately touching the outside wall of a chamber of the system to 2 feet from the outer wall of a chamber of the system, 0.1 to 1.5 feet, or 0.5 to 1 foot from the outer wall of a chamber of the system.

The mobile detector 195 runs with power input according to input parameters. The detected data is stored in memory and processing of the data with calibration parameters is performed. Raw data or the processed and calibrated data can be stored in memory and accessed by a processor. The mobile detector 195 can include memory and a processor physically coupled to it or the mobile detector can transmit the data to a remote computing device that includes the memory and processor. While illustrated with only one mobile detector 195, the systems disclosed herein can include multiple mobile detectors. For example, two to six, or three to five detectors can be utilized in the systems.

The radiation detector 550, may be, for example, a photon energy resolving spectrometer. In an embodiment, the radiation detector 550 is capable of detecting photons in the X-ray range and gamma-ray ranges. For example, for X-rays, energies of 100 eV to 100 keV may be detectable. Additionally, for photons in the gamma ray energy range, 1 keV to 20 MeV, such as 10 keV to 15 MeV, or 50 keV to 5 MeV is sufficient for most applications. In an embodiment, the radiation detector is capable of detecting one or more of alpha, beta, gamma, x-ray or neutron radiation or other emitted charged particles. In an embodiment, the radiation detector is not capable of neutron detection.

In an example, the radiation detector 550 is a solid-state scintillator-type spectrometer. Scintillators are materials that emit flashes or pulses of light when they interact with ionizing radiation. Scintillator crystals are used in radiation detectors for gamma-rays, X-rays, cosmic rays, and particles characterized by an energy level of greater than about 1 keV.

A spectrometer includes the scintillating crystal (or other scintillator) with an element for detecting the light produced by the crystal when it interacts, or “scintillates,” when exposed to a source of radiation, e.g., a photodetector. The photo-detector produces an electrical signal proportional to the intensity of the scintillation (or light pulses received from the scintillator material). The electrical signal is then processed in various ways to provide data on the radiation.

In an example, the radiation detector used herein may be a scintillating crystal device, such as, a NaI crystal that is doped with thallium, germanium, cesium bromide, or lanthanum bromide.

In any of the above embodiments, a controller 168 is further provided to control, communicate with, and/or adjust the ion source 102, the pre-analyzer accelerator 105, the mass analyzer 104, the main accelerator 113, the ERS 137, the beam scanner 119, and the angle corrector lens 120. While connections are not shown in FIG. 1, the controller is normally coupled by a communications cable to the various components it controls. Wireless communication can be used.

The controller 168 can also be coupled to one or more power supplies for the components. The controller 168 may also be communicatively coupled to the mobile detector 195 associated with the ion implantation system 100 and, in some embodiments, the railway 196, 296, 396 on which the mobile detector 195 travels.

The controller 168 may comprise a computer with a processor and data storage, and may be operable to receive measurement values of characteristics of the ion beam and adjust parameters accordingly. It can also be configured, for example, by software or hardware to receive signals from the mobile detector 195 and process them to produce reports and alerts to an operator via a display. In addition, the controller 168 can be configured to process the signals from the mobile detector 195 and make determinations of whether threshold levels of unknown radiation or known and unwanted radiation are present. The controller 168 can also control a power supply or other components to shut down the beamline operations in the event that threshold levels of radiation are reached.

A known or unknown radiation determination can be made by comparing one or more signal spectra to a database of known e X-ray or gamma-ray signatures, e.g., the National Nuclear Materials and Signatures Database. Furthermore, the signals from the mobile detector 195 can be processed to determine where the high energy emissions are originating from in the ion implantation system 100.

The mobile detector system disclosed herein can be initially designed to match a given facility location and ion implantation system. Geometrical features, such as, for example, wall dimensions, ceiling heights, or other equipment, and ion implantation system dimensions, including, e.g., a beam path 101 location in the space, can be entered into computer aided design (CAD) software, such as CREO. A mobile detector system can then be designed to be mounted to the walls or ceiling of the facility, or otherwise on pylons or the floor. The designed mobile detector system would in an embodiment, have a railway that runs about the same distance from the beamline or the exterior of the ion implantation system.

A mobile detector system and mobile detector 195 would then be designed for the ion implantation system. In most cases, a mobile detector 195 as depicted in FIG. 5 should be sufficient, but if additional arms or joints are needed for longer reaches or difficult to reach areas, these could be accounted for in the design. The railway can be installed in various locations associated with the ion implantation system 100 as the facility walls, ceilings and other equipment require.

Once installed with a new or pre-existing ion implantation system 100, the ion beam 101 of the system would be started or restarted and calibrated. During calibration, the mobile detector 195 would be sent out to locations along the ion beam 101 most likely to have a miscalibration and check each spot to make sure it is within correct operation parameters. For example, the mobile detector 195 would first be sent out to the ion source 102, then the first turn of the beamline in the mass analyzer, e.g., approximately where the mobile detector 195 is shown in FIGS. 1 and 3. If no anomalous radiation is detected then the mobile detector 195 is sent to slowly scan at the mobile LINAC accelerator 113, the ERS 137, and the beam scanner 119. Finally, the mobile detector 195 slowly scans at the end terminal near the workpiece 134 and workpiece support 175. In an embodiment, the mobile detector 195 may also be moved to a workpiece holding area.

A slow scan may involve a single pass at a low rate of speed, such as, 0.1 to 10 cm/min, e.g., 1 to 5 cm/min, or 1.5 to 3 cm/min. A slow scan can also involve a back and forth scan multiple times, such as 1 to 30 times, e.g., 2 to 10, or 3 to 6 times. If multiple scans are being done, the speed can be faster, e.g., 1 to 100 cm/min, e.g., 10 to 50 cm/min, or 15 to 30 cm/min.

If a radiation anomaly is found, the controller 168 in communication with the mobile detector 195 can cause the mobile detector 195 to zoom-in on the radiation where it is highest. For example, the mobile detector 195 may detect a 2× normal radiation anomaly as it is scanning, as it continues to scan it senses this decreasing, so it reverses or cycles around to within, e.g., 500 cm, 100 cm, or 50 cm of the previously detected radiation anomaly, or until it senses radiation increasing. It then slows down and continues to scan until the radiation stops increasing. The mobile detector 195 would then extend in the x-axis closer to the ion implantation system 100 and then in a similar ways as above, begin rotating the radiation detector 550 to orient itself towards the highest radiation. Once the best location for detecting the highest radiation is achieved, the mobile detector 195 would stop and record data until an operator intervenes and restarts the scanning protocol. In an embodiment, the mobile detector 195 is configured to telescope and extend the radiation sensor to be within 20 cm, 10 cm, or 5 cm of the outside wall of a chamber or component of the ion implantation system, including touching the outside wall of the chamber or component or workpiece. Distances relating to the mobile detector 195 and radiation detector 550 may be calculated based on the shortest distance between a surface of the radiation detector 550 and a surface of the ion implantation system chamber or component or workpiece.

In an embodiment, the controller 168 causes the mobile detector 195 to constantly traverse the railway while the ion implantation system is in operation, looking for radiation and zooming in on anomalies to slowly scan, stop, and monitor at the location of highest radiation. This passive scanning mode could be particularly helpful, for example, if a quadrupole used for beam focusing is not operating correctly, but the software on the ion implantation system operator's display panel indicates it is operating normally.

In an embodiment, the controller 168 causes the mobile detector to spend the most time in the most likely areas of the ion implantation system to produce high-energy radiation beam strikes, X-rays or gamma rays. These areas may be near the LINAC accelerator 113, the ERS 137, and the beam scanner 119. Other areas of particular interest are at the end terminal where a workpiece 134 and workpiece support 175 are present, and near a Faraday cup, dose cup, bending magnets, or another structure that may be impacted by the beam or cause a deflection. In an embodiment, the mobile detector 195 is configured to move along the railway at a first rate to multiple preprogrammed locations and at these locations scanning for radiation anomalies at a second rate, wherein the second rate is less than the first rate. The second rate may be, for example, 50% to 0.01% of the first rate, such as 40% to 0.1%, or 10% to 1% of the first rate.

In an embodiment, one or more mobile detectors 195 are assigned to one or more of areas and either (1) scan slowly in one direction and then move quickly to the next area of interest, then cycle back around; or (2) scan back and forth, once, twice, or more and then move on the next area of interest. In another example, there are multiple mobile detectors 195 and a separate mobile detector 195 is assigned to scan back forth at each area of interest.

The mobile detector 195 is coupled to the controller 168 that is configured to process through a processor and data storage, the incoming signals from the radiation detector 550. By the intensity of the signal and knowing the location of the mobile detector 195, the controller 168 is configured to determine a location where the system is experiencing a radiation event (detected photon energy).

In addition, the controller 168 can interpret the signal from the mobile detector 195 to determine a type of radiation, e.g., X-ray or gamma ray, or particular spectra data that match known spectra data. The controller 168 can cause this information to be stored in data storage and provide an operator with this information via a graphical user interface on a display. In addition, the controller can cause the system to shut down if a threshold level of radiation is detected, as described further below.

In an embodiment, the controller 168 processes the data from the mobile detector 195 and calculates a cooldown period after which the radiation will be below a predetermined threshold at a given distance. The operator can use this information to determine when and how maintenance can take place on the device to resolve the issue.

In another operation routine, the mobile detector system can also survey the entire beam line at the end of a test/running cycle and check the ion implantation system 100 for decaying radiation before personnel enter the machine for maintenance, so that it can be done in a more efficient manner.

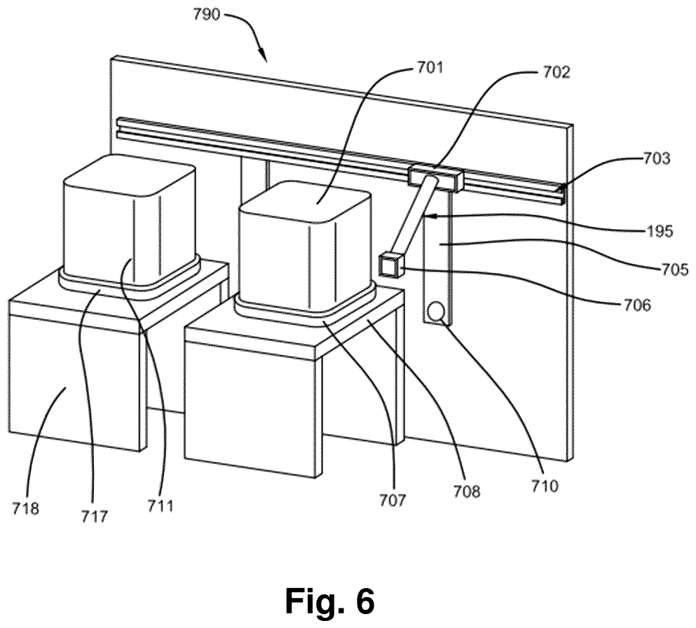

FIG. 6 discloses another embodiment of a mobile detector system 790 that is a wafer/workpiece radiation dosimetry monitoring system that measures the activated or decaying radioactive isotopes within implanted wafers after they are removed from the workpiece support.

FIG. 6 discloses a first FOUP 701 and a second FOUP 711, as explained above a FOUP is a type of workpiece cassette. Each FOUP is depicted sitting on top of their associated first and second bases 707, 517 and first and second holder stations 708, 718. The first and second FOUP 701, 711 are in a holding area sitting near an ion implantation system 100.

The mobile detector system 790 comprises a railway 703 mounted on a wall in this embodiment. The railway 703 extends around at least a portion of a workpiece cassette holding area. The mobile detector 195 is moveably coupled to the railway 703 as in the embodiments described above. In this embodiment, the mobile detector 195 travels along the railway 703 to a position near the first FOUP 701 aligning itself either in front or to the side for moving up and down and/or across the face of the wafer. At this point the mobile detector 195 is ready to scan to each wafer at close range, e.g., shortly after it is transferred from the implantation chamber and enters its slot in the FOUP. In an embodiment, the mobile detector 195 is configured to move to a side of a FOUP 701 and change position to be next to a most recently implanted workpiece after it enters the workpiece cassette. Next to the workpiece means on the same level as the workpiece. When the workpieces are in a vertical arrangement, the radiation detector 550 on the mobile detector 195 may be to the side and centered on the vertical height of the slot in which the workpiece is located. After the first FOUP 701 is scanned, the mobile detector 195 then moves to the second FOUP 711 and repeats the process. Alternatively, the second FOUP 711 may be moved into the place where the first FOUP 701 was previously.

The mobile detector system 790 also has a radioactive check source 710 near the mobile detector 195 and the FOUP holding area. This radioactive check source provides a baseline calibration for the mobile detector 195 before or even during use. This provides the operator with a known value for radiation that can be used to make sure the mobile detector 195 is working properly. The radioactive check source 710 may be housed in a shielded enclosure that opens during the detector check.

Prior to operation and after the radiation has been sufficiently characterized, the mobile detector 195 may drop down vertically to a resting position. The mobile detector 195 may also be designed to withdraw into the face of the implanter when at rest. In an embodiment, the controller 168 has predetermined the location where the first and second FOUP 701, 711 are expected to be and the motion that the mobile detector system 790 allows is done in effort to avoid collisions with the first and second FOUP 701, 711 or their base 707, 717 and holder stations 708, 718. In an embodiment, the mobile detector system 790 will be compatible with facilities that use OHT (overhead hoist transport) wafer handling systems.

In an embodiment, the controller 168 causes the mobile detector 195 to start at a side location of the wafer slot and when a first wafer comes in from the implantation chamber, then the mobile detector 195 is caused to move near it, e.g., 0.1 to 20 cm, 0.5 to 10 cm, or 1 to 3 cm. The controller 168 may coordinate the movement of the wafer and the mobile detector 195 so that as subsequent wafers are deposited into the FOUP the mobile detector 195 is moved into close proximity with the newly deposited wafer looking for anomalies. The mobile detector 195 may then scan the wafers for some time, monitoring any anomalous situations where the radiation exceeds expected norms.

The mobile detector 195 may also be controlled to hone in on radiation hot spots, for example, in a manner as disclosed above. This mode enables the mobile detector 195 to automatically move to the area exhibiting the highest radioactivity. Typically this will be the most recently implanted wafer, but if a prior treated wafer is more radioactive for some reason, the sensor will remain on it until it cools down to normal levels. An alert can be triggered if this happens. Optionally, the mobile detector 195 can alert the operator to this and continue scanning other wafers. Then, after all wafers are scanned the mobile detector 195 may return to the anomalous wafer.

With the close monitoring provided by the mobile detector system 790 the controller 168 processes the data from the sensor and can calculate an accurate time to release the FOUP from the holding area for the wafers to be removed and transferred. In addition, before the FOUP is released, the mobile detector 195 can perform a final scan to confirm the radiation level is below a threshold for the wafers. This process may also involve a step of first checking the mobile detector 195 is operating correctly with the known radioactive check source 710.

In an embodiment, the mobile detector system 790 is a subsystem of or combined with a larger system, such as those shown in FIG. 1 or 2. For example, the mobile detector 195 may move from the railway of FIG. 1 or 2 into the wafer holding area near an end terminal of the ion implantation system 100 and conduct the wafer monitoring method after or before conducting the startup/calibration monitoring or passive ion implantation system operation monitoring disclosed above. This embodiment may benefit from multiple mobile detectors 195, such as a first mobile detector 195 dedicated for use with the system as a whole, and a second mobile detector 195 dedicated for use in for wafer monitoring.

In many wafer loading/unloading systems, there is an optical sensor that moves vertically and determines which slots of the FOUP are populated with wafers. In a similar embodiment to that described above, a radiation detector could be mounted on the wafer sense arm to capture the radiation as the optical sensor detects the presence of wafers. Its movement routines could be altered to customize the device to not allowing checking optically for the presence of wafers, but checking their radioactivity levels.

In another embodiment, the decay rate could be measured in such a way that if measurements were separated with sufficient time, or a wafer at a certain interval of wafers i.e., every 4 or 8 wafers, and then predict when the wafers can be handled. In an embodiment, measuring the radiation from an interval of wafers, can be done, e.g., every 2 to 10, such as every 4, 6, or 8 wafers, coming out of the implanter could be an application for when the measurement time to get a reasonable radiation measurement, (for example, it may takes 60 seconds for the measurement to stabilize) is long and affects the mechanical throughput of the machine.

This system can also be used to determine if the wrong type of workpiece/wafer is being implanted, the prompt and decay radiation of activated isotopes in the wafer can be identified using the mobile detector 195 that is scanning in this area.

Applications for the mobile detector system outside of wafer implantation systems include uranium fission research reactors, such as, measuring and monitoring exiting samples from irradiation in the core. With research fission reactors, the main goal is to have control over the emitted radiation for samples. Fission industrial power-generating reactors could also benefit from a passive radiation detector system looking for leaks in feed water/water exhaust. This type of reactor is a fission reaction that utilizes a sustained nuclear fission of U-235 or “breeding Uranium”, subsequently spinning a turbine with heat generation. Other types of reactors utilize sodium as a cooling volume instead of water. Thorium salt reactors, and fusion research reactors can also benefit from a mobile radiation surveying before, during, and after operation. An application can also be found in research accelerators to measure the relative radiation produced at different parts of the beamline passively during operations and post operation of a beam (decaying radiation from beamline components).

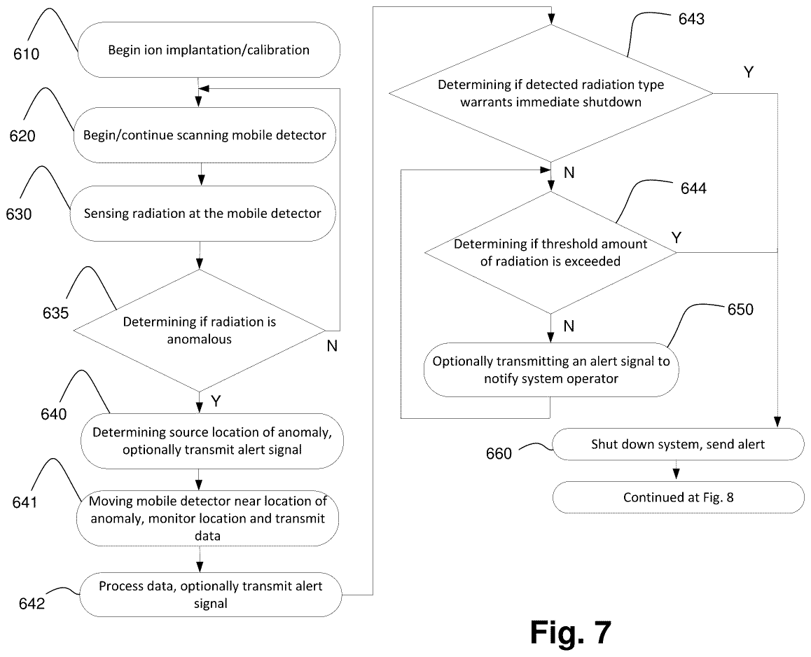

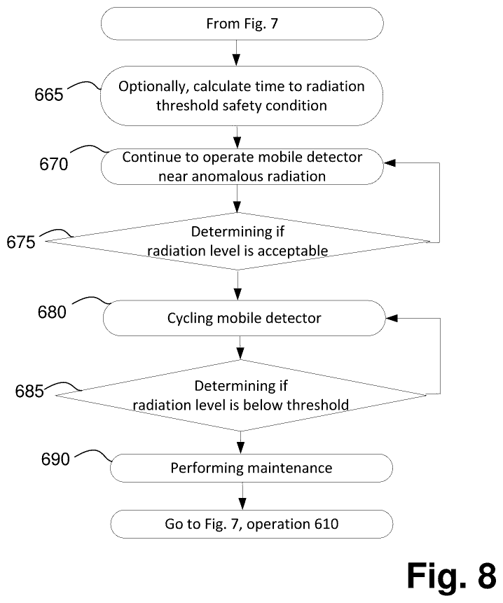

In reference now to FIGS. 7 and 8, an exemplary methodology associated with the mobile detector and controller used in the ion implantation system will be further described. FIG. 7 is a flowchart of an example method for mobile detection of radiation in an ion implantation system, processing the signal received therefrom, and operating the ion implantation system.

At operation 610, ion implantation or calibration operations are conducted, such as those described above in a system such as shown in FIG. 1 or 2. In particular, light ion/high-energy ion implantation is conducted, which may be conducted by exciting ions with an atomic number of 1 to 10 and accelerating the ions at an energy of 300 keV to 20 MeV. The system and methods used herein can also be conducted with ions being accelerated at 10 keV to 30 MeV.

At operation 620 the mobile detector begins scanning on its associated railway. The scanning routine can be either the constant scan wherein the mobile detector moves along the path at a constant rate or 10% within a constant rate, or a focused scan wherein the mobile detector moves faster (a first rate) in transitional locations and slowly (at a second rate) at selected portions where anomalous radiation is more likely to occur. The scanning routine may be run once at calibration, and can continue in a cycle thereafter, wherein the entire railway is traversed multiple times. The scanning can be in a forward and/or reverse direction.

In an embodiment, when scanning, the mobile detector stays at a level that is closest to the beamline. In another embodiment, the mobile detector when scanning in an x-direction also moves up and down in a y-direction (or perpendicular to the railway). In an embodiment, the mobile detector scans at a first y position in a first cycle through the railway, in a second y position in a subsequent cycle, and in a third, fourth, fifth, . . . n^{th} y positions in subsequent cycles.

Operation 620 can also be applied to scanning the mobile detector scanning the workpieces in the workpiece cassette as explained above.

At operation 630 the mobile detector detects radiation. The controller may receive the signal that is transmitted from the mobile detector. The signals can be transmitted and received through wired or wireless connections, but wired connections may provide better reliability. Some or all processing can optionally be done on a processor housed in the mobile detector.

At operation 635 the processor determines whether anomalous radiation (e.g., high energy photons) is detected by analyzing the signal from mobile detector. If no anomalous radiation is detected this process may continue indefinitely or until anomalous radiation detected. Anomalous radiation may be any radiation of a different type or threshold amount over what is expected given conditions programmed and stored in memory accessible to the controller.

At operation 640 the signal is processed to determine a source location of the detected radiation. Optionally, at the point that an anomaly is detected an alert is immediately provided.

At operation 641, the mobile detector is moved near the location of the anomalous radiation and the location is monitored for a period of time and data is transmitted. Operations 640 and 641 may happen concurrently, that is the moving mobile detector 195 is controlled to move near the location of the anomalous radiation source. These operations can be triggered when the mobile detector moves and detects a difference, either higher or lower, in radiation. Some threshold of variance would be set, e.g., above 10%, above 25%, above 50%, or above 100% variance from expected values. Expected values may be set from preprogrammed data and/or from previously recorded data from prior scanning cycles. Once this zeroing-in operation is triggered, the mobile detector is then controlled to move in the direction of the rising radiation or opposite the direction of the decreasing radiation as discussed further above. After the highest radiation value on the railway in the x-direction is determined, the mobile detector can then move in the y and optionally z-directions to further zoom in on the radiation anomaly where the radiation count is highest. Location data of the mobile detector may then be provided to the processor by sending coordinate (x, y, and optionally z) values. The location of the various components of the ion implantation system may also be input to data storage accessible to the processor in coordinate form. Coordinates of the radiation anomaly can then be provided to an operator in relation to the location in the ion implantation system.

Optionally, when the mobile device is scanning the workpiece cassette for anomalies, further zooming in may not be requested. However, in an embodiment, the mobile device may be moved closer or to another side of the workpiece for further monitoring and identification of the highest radiation area of the workpiece.

At operation 642, the transmitted data from the mobile detector is processed to determine a type and amount of radiation. This can be done by comparing the detected data (e.g., in the form of a spectra) with known spectra of selected types of radiation energy.

At operation 643, a determination is made on whether the radiation type warrants immediate shutdown. This may be based on a determination that the detected data matches a known (i.e., stored and accessible to a processor of the system in memory storage) radiation spectrum to a certain level of certainty. The determination may also be a determination that the detected data does not match a known radiation spectrum and is thus unknown. Optionally, an alert signal may be immediately transmitted to a display and/or the system shut down (operation 660) once this determination is made.

If the radiation does not warrant immediate shutdown, at operation 644, the first signal and second signal are processed to determine whether a threshold level of radiation energy is exceeded. The threshold may be some level that has been designated as dangerous over a certain period of time, or a lower level.

If the threshold is determined to be exceeded, a signal will be transmitted to shut down the system, and at operation 660 the system is shut down. By shut down, it is meant that the beamline operations cease such that the beam impacts causing the detected radiation stop. In an example system, the beamline operations are shut down immediately and automatically. However, in some situations, such as if the threshold is set lower than a pre-defined level, an alert may be triggered and provided to an operator at 650, for example, through a display. The operator may then have an opportunity to shut down the operation manually, and in an example operation, the system may be automatically triggered to shut down if no further input is received from the operator within a certain time after the first alert is transmitted, and/or if the detectors continue to identify the threshold being exceeded.

At operation 660 one or more alert signals may be transmitted to a display or some other alerting device. These signals include an identification of the spectra as a certain known type or an unknown type, a display of the detected spectra data, the location of the anomalous radiation with respect to the ion implantation system and/or the likely component where the beam strike is taking effect, information identifying a layer of the liner that is being impacted, a total level and/or information as to how the level relates to the threshold, and a time to imminent shutdown. Operation 660 can also be reached through a manual shutdown by the operator, e.g., after one of the alerts mentioned above is displayed to the operator.

After shutdown at 660, the method continues at FIG. 8.

FIG. 8 is a continuation of the method of claim 7, wherein post-shutdown activities are disclosed. The detected prompt radiation and possible decay radiation from the anomalously activated materials can be used to analyze radiation hazards after shutdown of the ion implantation system. Thus, detection/analysis operations will continue even after the beamline operations are shut down to assess any lingering decay radiation.

At operation 665 the controller can process the received data and calculate a time to a radiation threshold condition. This time can be displayed to the operator, so that maintenance preparations can be made.

At operation 670 the mobile detector continues to monitor near the area by detecting and transmitting data. Updates as to a time to threshold radiation condition can be provided to the operator during this process. The controller continues to process the data, until at operation 675 the controller determines that the radiation level is acceptable (or no longer anomalous).

At operation 680, the mobile detector is activated to move along the railway and check the rest of the ion implantation system in a manner used before. This is to ensure that there are no other radiation conditions not previously detected.

At operation 685 the controller determines that the radiation level is acceptable for the entire ion implantation system and an alert can be transmitted expressing this to the operator.

At operation 690 maintenance is performed, such as by a human entering the area and addressing the anomalous area.

After maintenance is finished, the operations can restart at FIG. 7, operation 610.

Practice of the invention will be more fully understood from the foregoing examples, which are presented herein for illustrative purposes only, and should not be construed as limiting the invention in any way.

### EXAMPLES

### Example 1

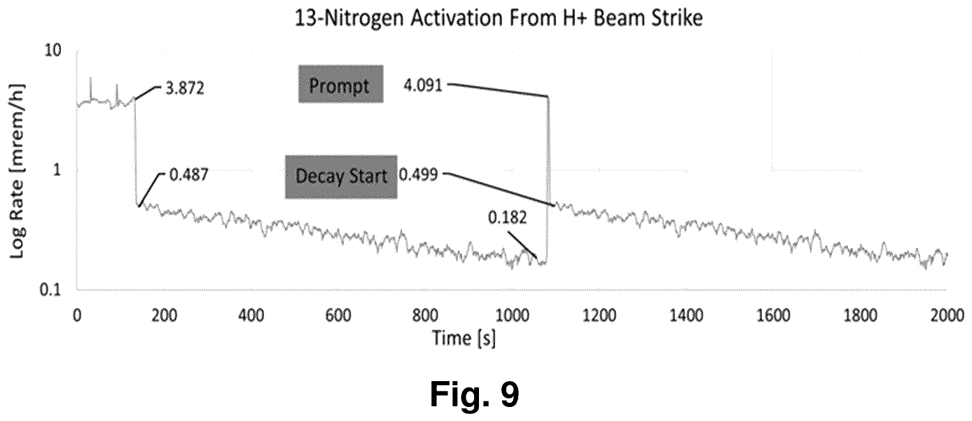

FIG. 9 is a graph of data capturing radiation decay data from the ¹³N production from the ¹²C(p, γ)¹³N fusion reaction on an AXCELIS PURION XEMAXimplanter. FIG. 9 displays a characterization between the prompt gamma-ray radiation and subsequent decay radiation from H+ beam strike.

This data was taken 10 cm away from a graphite target. H+ was accelerated to 1100 keV and the beam current was set at 200 μA. A predetermined time-to-hold this piece of graphite, for example, is on the order of 1000 seconds. This illustrates the value of an active tracking system that can move in close to a particular area for this unwanted beam/beam liner combination. Especially at lower beam currents, such as beam currents below 100 uA, e.g., 50 uA to 1 uA, or 25 uA to 0.1 uA, stationary detectors will not correctly characterize every source of activation radiation within the beam line the way a mobile detection system will. At lower beam current, the generated radiation will typically be lower with linear dependence to beam current. For example, at 1 mA of beam current there may be a resulting radiation field of 1 mRem/Hr. At 0.01 mA you could have 0.01 mRen/Hr, making the detection and reliable measurement of radiation difficult when it the dose rate signal has a lower signal height when compared to background (˜0.015 mRem/Hr).

### Example 2

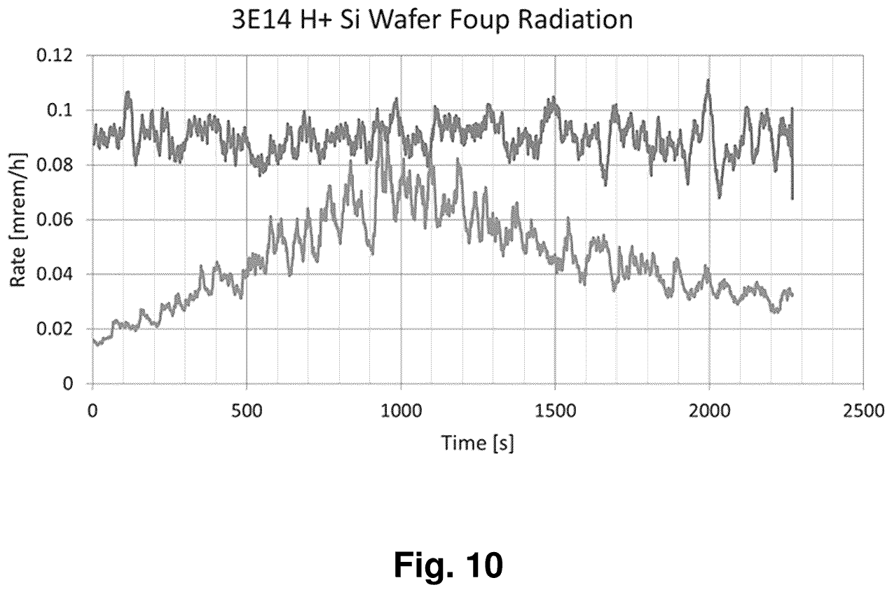

FIG. 10 is a graph showing radiation detected from a 3E¹⁴ H+ implant provided from an AXCELIS PURION VXE implanter. The radiation data shows dose rate in units of mRem/Hr on the y-axis vs time in units of seconds on the x-axis. This data was collected to correspond to detecting radiation in wafers in a FOUP as described above.

The data on the graph starts (time 0) when a first wafer comes back from implant and is stopped when the last wafer comes back from implant. With a stationary detector placed mid-way up the side of the FOUP, the resulting orange data set can be seen peaking around 1000 seconds, as the wafer slot that is closest to the detector is filled by a wafer coming back from implant.

The plot at the top of the graph was produced by a geometric normalization done by manually moving the radiation detector up 1 wafer slot every time a wafer comes back from implantation simulating a mobile detector moving along the side. Using the proposed mobile detector to move when each newly implanted wafer comes back will produce a data set like this, but will be more accurate as the detector will be closer to each wafer. At each point of the post-implant dosimetry, the radiation coming from each wafer can be correctly characterized.

Although the disclosure has been shown and described with respect to a certain applications and implementations, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including any reference to a “means”) used to describe such components are intended to correspond, unless otherwise indicated, to any component which performs the specified function of the described component (i.e., that is functionally equivalent), even though not structurally equivalent to the disclosed structure, which performs the function in the herein illustrated exemplary implementations of the disclosure.

In addition, while a particular feature of the disclosure may have been disclosed with respect to only one of several implementations, such feature may be combined with one or more other features of the other implementations as may be desired and advantageous for any given or particular application. Furthermore, to the extent that the terms “includes,” “including,” “has,” “having,” and variants thereof are used in either the detailed description or the claims, these terms are intended to be inclusive in a manner similar to the term “comprising.”

What is claimed is:

1. A system comprising:
a mobile detector system associated with an ion implantation system;
the ion implantation system comprising:
an ion source that generates ions and produces an ion beam along a beamline, a mass analyzer positioned downstream of the ion source that generates a magnetic field; and an ion accelerator downstream of the mass analyzer;
the mobile detector system comprising:
a railway extending around at least a portion of the ion implantation system or a holding station for a workpiece cassette; and
a mobile detector moveably coupled to the railway and including a radiation detector.

2. The system of claim 1, Wherein the mobile detector comprises an arm with the radiation detector coupled to an end of the arm.

3. The system of claim 1, wherein the ion accelerator is configured to accelerate ions to an energy of 10 keV to 30 MeV or wherein the ions are selected from elements with an atomic number of 11 or less.

4. The system of claim 1, wherein the mobile detector is configured to telescope and extend the radiation detector to be within 20 cm of an outside wall of a chamber or component of the ion implantation system.

5. The system of claim 1, wherein the mobile detector is configured to zoom-in on a radiation anomaly where a radiation count is highest.

6. The system of claim 1, wherein the mobile detector has at least two degrees of freedom of motion in addition to the motion imparted by movement along the railway.

7. The system of claim 1, wherein the mobile detector is configured to move along the railway scanning for radiation anomalies at a constant rate or within 10% of a constant rate.

8. The system of claim 1, wherein the mobile detector is configured to move along the railway at a first rate to multiple preprogrammed locations and at the locations scanning for radiation anomalies at a second rate, wherein the second rate is less than the first rate.

9. The system of claim 8, wherein the multiple preprogrammed locations include one or more of the ion accelerator, an ERS, a beam scanner, an end terminal, and a workpiece holding area.

10. The system of claim 1, wherein the mobile detector is configured to move to a side of a workpiece cassette, and change position to be next to a most recently implanted workpiece after the most recently implanted workpiece is returned to the workpiece cassette.

11. The system of claim 1, further comprising a processor that is configured to receive input signals from the radiation detector; process the input signals to identify detected radiation as known or unknown; and transmit an alert to a display and/or shutdown the ion implantation system if a threshold of unknown or particular known radiation is identified.

12. The system of claim 1, wherein the radiation detector is a gamma ray spectrometer.

13. The system of claim 1, wherein the mobile detector cycles around the railway during ion implantation operations.

14. A method of conducting ion implantation operations comprising the operations of:
conducting ion implantation on a workpiece or calibrating an ion implantation system;
detecting radiation at a mobile detector, the mobile detector moveably coupled to a railway;
determining if detected radiation is anomalous;
if anomalous radiation is detected, then moving the mobile detector to a source of the anomalous radiation, wherein moving the mobile detector to a source of the anomalous radiation comprises moving the radiation detector closer to the ion implantation system or workpiece;
determining if the anomalous radiation warrants shutdown of the ion implantation system.

15. The method of claim 14, further comprising:
shutting down the ion implantation system, and continuing to monitor radiation at the mobile detector; and
determining if a radiation level is below a predetermined threshold based on data received from the mobile detector, wherein a radiation detector of the mobile detector is within 20 cm of an outside wall of a chamber or component of the ion implantation system or workpiece; and sending an alert that a radiation threshold level is below a set limit.

16. The method of claim 15, further comprising after detecting that anomalous radiation is anomalous, calculating and displaying a time to an expected radiation threshold condition.

17. The method of claim 14, wherein conducting ion implantation comprises exciting ions with an atomic number of 1 to 11 and accelerating the ions at an energy of 10 keV to 30 MeV.

18. The method of claim 14, further comprising automatically shutting down the ion implantation operations if a type of radiation is unknown or threshold level of radiation is exceeded.

19. A system comprising:
a mobile detector system associated with a holding station for a workpiece cassette, comprising:
the mobile detector system comprising:
a railway extending around at least a portion of the holding station for a workpiece cassette configured to house workpieces;
a mobile detector moveably coupled to the railway;
the mobile detector comprising an arm with a radiation detector coupled to an end of the arm;
the mobile detector configured to move to a side of a workpiece cassette, and change position to be within 10 cm of a most recently implanted workpiece after the most recently implanted workpiece enters the workpiece cassette;
the mobile detector system configured to monitor the workpieces for a radiation anomaly and provide an alert regarding a detected radiation anomaly to an operator on a display.

20. The system of claim 19, wherein the mobile detector is configured to continue to monitor a detected radiation anomaly until a radiation threshold condition is reached and alert an operator on a display regarding the radiation threshold condition.
